(19) United States
(12) Patent Application Publication
(10) Pub. No.: US 2026/0082698 A1
(43) Pub. Date: Mar. 19, 2026

(54) ARRAY SUBSTRATE AND A DISPLAY PANEL

(71) Applicant: Guangzhou China Star Optoelectronics Semiconductor Display Technology Co., Ltd., Guangzhou (CN)

(72) Inventors: Lihong GUI, Guangzhou (CN); Yoonsung UM, Guangzhou (CN)

(73) Assignee: Guangzhou China Star Optoelectronics Semiconductor Display Technology Co., Ltd., Guangzhou (CN)

(21) Appl. No.: 19/023,753

(22) Filed: Jan. 16, 2025

(30) Foreign Application Priority Data
Sep. 18, 2024 (CN) 202411302808.5

(51) Int. Cl. H10D 86/40; G02F 1/1362; H10D 86/60

(52) U.S. Cl. CPC H10D 86/441; G02F 1/136286; H10D 86/60

(57) ABSTRACT

The present disclosure relates to an array substrate and a display panel. The array substrate includes a first electrode and a second electrode. The second electrode includes an edge electrode and a plurality of branch electrodes, with the branch electrodes connected to one side of the edge electrode and extending along a first direction. The plurality of branch electrodes are arranged at intervals along a second direction, forming slits between two adjacent branch electrodes. In a top view of the array substrate, the side of the branch electrodes close to the slit is featured with concave portions and convex portions that are alternately arranged in the first direction.

### CROSS-REFERENCE TO RELATED APPLICATION

This present disclosure claims priority to Chinese Patent Application No. 202411302808.5, filed on Sep. 18, 2024, the disclosure of which is incorporated herein by reference in its entirety.

### TECHNICAL FIELD

This present disclosure relates to display technologies.

### BACKGROUND

In conventional display panels employing fringe field switching technology, the pixel electrode and the common electrode are arranged on the array substrate on different layers. An arrangement of patterning is generally implemented for the pixel electrode, and the branch electrodes are in shape of straight bars.

During the research and practice process of the prior art, it has been discovered that conventional fringe field switching technology cannot meet the requirement of high response rate for liquid crystal driving efficiency.

### SUMMARY

In one or more embodiments of the present disclosure, an array substrate includes a scanning line, a data line, a first electrode and a second electrode. The data line intersects with the scanning line to form a plurality of pixel regions. The first electrode and the second electrode are disposed in the pixel regions, wherein the first electrode and the second electrode are disposed on different layers, and the first electrode and the second electrode are configured to drive liquid crystal to deflect. One of the first electrode and the second electrode is a pixel electrode, while the other of the first electrode and the second electrode is a common electrode. The first electrode is a planar electrode, and in a top view of the array substrate, the second electrode overlaps with the first electrode. The Second electrode includes an edge electrode and a plurality of branch electrodes. The plurality of branch electrodes are connected to one side of the edge electrode and extend along a first direction intersecting an extension direction of the scanning line. The plurality of branch electrodes are arranged at intervals along a second direction, which is parallel to the extension direction of the scanning line, a slit is formed between two adjacent branch electrodes. In the top view of the array substrate, the side of the branch electrode close to the slit is featured with concave portions and convex portion and in the first direction, the concave portions and the convex portions are alternately arranged.

In one or more embodiments of the present disclosure, a display panel includes an opposed substrate, a liquid crystal layer, and an array substrate, wherein the liquid crystal layer is disposed between the opposed substrate and the array substrate. The array substrate includes a scanning line, a data line, a first electrode and a second electrode. The data line intersects with the scanning line to form a plurality of pixel regions. The first electrode and the second electrode are disposed in the pixel regions, wherein the first electrode and the second electrode are disposed on different layers, and the first electrode and the second electrode are configured to drive liquid crystal to deflect. One of the first electrode and the second electrode is a pixel electrode, while the other of the first electrode and the second electrode is a common electrode. The first electrode is a planar electrode, and in a top view of the array substrate, the second electrode overlaps with the first electrode. The Second electrode includes an edge electrode and a plurality of branch electrodes. The plurality of branch electrodes are connected to one side of the edge electrode and extend along a first direction intersecting with an extension direction of the scanning line. The plurality of branch electrodes are arranged at intervals along a second direction, which is parallel to the extension direction of the scanning line, a slit is formed between two adjacent branch electrodes. In the top view of the array substrate, the side of the branch electrode close to the slit is featured with concave portions and convex portions, and in the first direction, the concave portions and the convex portions are alternately arranged.

### BRIEF DESCRIPTION OF THE DRAWINGS

FIG. 1 is a top view schematic diagram of a Liquid Crystal Display (LCD) panel in the prior art.

FIG. 2 is a schematic diagram of the electric field intensity of a Liquid Crystal Display (LCD) panel in the prior art.

FIG. 3 is a top view schematic diagram of an array substrate according to one or more embodiments of the present disclosure.

FIG. 4 is a cross-sectional schematic diagram of a structure of an array substrate according to one or more embodiments of the present disclosure.

FIG. 5 is a cross-sectional schematic diagram of another structure of an array substrate according to one or more embodiments of the present disclosure.

FIG. 6 is a schematic diagram of a structure of a pixel region in FIG. 3.

FIG. 7 is a schematic diagram of an arrangement of a liquid crystal in a portion of FIG. 6.

FIG. 8 is an enlarged schematic diagram of part A in FIG. 6.

FIG. 9 is a schematic diagram of another structure of a pixel region in FIG. 3.

FIG. 10 is an enlarged schematic diagram of part A in FIG. 9.

FIG. 11 is a schematic diagram of yet another structure of a pixel region in FIG. 3.

FIG. 12 is an enlarged schematic diagram of part A in FIG. 11.

FIG. 13 is a schematic diagram of a structure of a display panel according to one or more embodiments of the present disclosure.

### DETAILED DESCRIPTION

The technical solutions in the embodiments of the present disclosure will be clearly and completely described with reference to the accompanying drawings. It should be appreciated that the described embodiments are only some of the embodiments of the present disclosure, but not all of them. Based on the embodiments of the present disclosure, all other embodiments obtained by those skilled in the art without involving any creative labor are within the scope of the present disclosure. Furthermore, it should be understood that the specific embodiments described herein are only for the purpose of illustration and explanation of the present disclosure, and are not intended to limit the present disclosure. In the present disclosure, embodiments may be combined with each other but will not be redundantly described. Unless otherwise specified, directional terms such as “above” and “below” generally refer to directions of a device in its actual operation or working state, specifically the direction shown in the accompanying drawings; “inside” and “outside” refer to the outline of the device; and terms like “first”, “second”, and “third”, etc., are merely used as labels and do not impose numerical requirements or establish order.

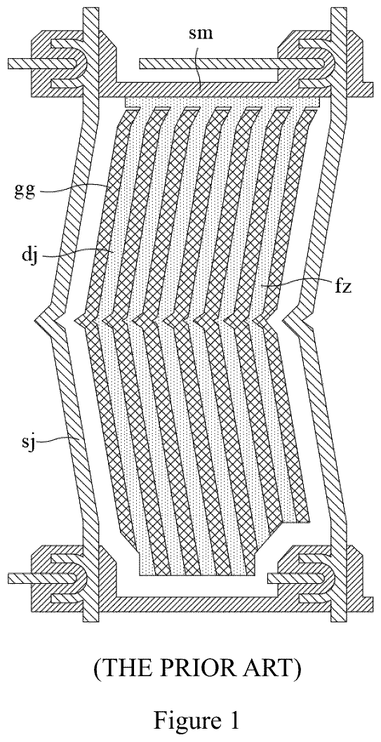

In a display panel employing fringe field switching technology in the prior art, an array substrate includes a scanning line sm, a data line sj, a pixel electrode dj, and a common electrode gg. The pixel electrode d and the common electrode gg are disposed on different layers. The pixel electrode dj is typically patterned, and a branch electrode fz of the pixel electrode dj is formed by two intersecting straight segments, as shown in FIG. 1.

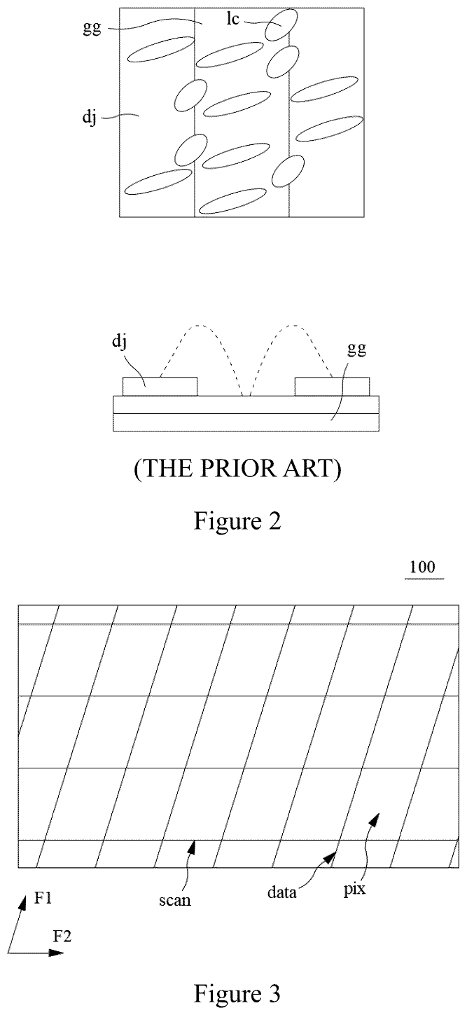

It should be noted that, as shown in FIG. 2, an electric field is generated between the pixel electrode dj and the common electrode gg. The edge region of the pixel electrode dj exhibits the strongest electric field intensity, where the response speed of a liquid crystal lc is the fastest. By intermolecular forces, the liquid crystal lc in this area will bring the liquid crystal lc in adjacent areas to rotate together.

An array substrate according to one or more embodiments of the present disclosure includes a first electrode and a second electrode, which generate an electric field to drive the liquid crystal to deflect. Branch electrodes with alternating concave portions and convex portions in a first direction are used to increase the edge region of the second electrode, so that more liquid crystal are distributed in the edge region of the second electrode, bringing more surrounding liquid crystal to rotate simultaneously, and accelerating the overall response speed of the liquid crystal.

One or more embodiments of the present disclosure provide an array substrate and a display panel, which will be described in detail below. It should be noted that the order of description of the following embodiments should not be interpreted as a limitation on the preferred order of the embodiments.

As shown in FIG. 3, which shows a top view schematic diagram of an array substrate 100 according to one or more embodiments of the present disclosure.

An embodiment of the present disclosure provides an array substrate 100, which includes a scanning line (scan) and a data line (data). In FIG. 3, a first direction F1 is parallel to the extension direction of the data line (data), but not limited to this. For example, the first direction F1 can also intersect the extension direction of the data line (data). A second direction F2 is parallel to the extension direction of the scanning line (scan), but not limited to this. For example, the second direction F2 can also intersect the extension direction of the scanning line (scan). The first direction F1 intersects the second direction F2 at a non-perpendicular angle.

The data line (data) and the scanning line (scan) are arranged to form a plurality of pixel regions (pix). Optionally, in the first direction F1 and the second direction F2, the pixel regions (pix) are arranged in an array. In other words, the plurality of pixel regions (pix) are arranged in rows along the first direction F1, and the plurality of pixel regions (pix) are arranged in columns along the second direction F2.

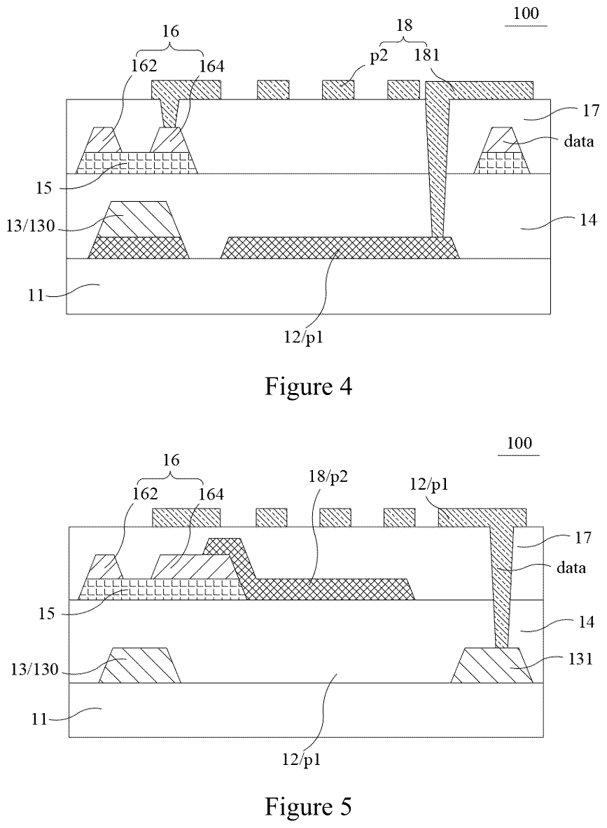

As shown in FIGS. 4 to 6, which show an array substrate 100 including a first electrode p1 and a second electrode p2. The first electrode p1 and the second electrode p2 are disposed in the pixel regions (pix).

Optionally, in some embodiments, the first electrode p1 and the second electrode p2 are arranged on different layers. The first electrode p1 and the second electrode p2 are configured to generate an electric field to drive liquid crystal to deflect. One of the first electrode p1 and the second electrode p2 is a pixel electrode, and the other is a common electrode.

It should be noted that in the following explanation the first electrode p1 is a common electrode and the second electrode p2 is a pixel electrode, but is not limited to this. For example, it is also possible that the first electrode p1 is a pixel electrode and the second electrode p2 can be a common electrode.

As shown in FIG. 4, which shows a schematic diagram of the hierarchical structure of the film layers of the array substrate 100 according to one or more embodiments of this present disclosure.

Optionally, the array substrate 100 includes a substrate 11, a common electrode layer 12, a first metal layer 13, a first insulating layer 14, an active layer 15, a second metal layer 16, a second insulating layer 17, and a pixel electrode layer 18.

The common electrode layer 12 is disposed on the substrate 11 and includes a first electrode p1. The first metal layer 13 is disposed on the common electrode layer 12 and includes a gate 130 and a scanning line (scan), with the gate 130 formed on the bottom. The first insulating layer 14 covers the first metal layer 13. The active layer 15 is disposed on the first insulating layer 14. The second metal layer 16 is disposed on the active layer 15 and contains a source 162, a drain 164, and a data line (data), with the source 162 and the drain 164 connected to the active layer 15. The second insulating layer 17 covers the second metal layer 16. The pixel electrode layer 18 is disposed on the second insulating layer 17, and includes a second electrode p2 and a shielding electrode 181, where the second electrode p2 is connected to the drain 164 and the shielding electrode 181 is connected to the first electrode p1. In the thickness direction of the array substrate 100, the shielding electrode 181 covers the data line (data), and the second electrode p2 overlaps with the first electrode p1.

The first metal layer 13 and the common electrode layer 12 are fabricated using the same mask. Similarly, the active layer 15 and the second metal layer 16 are also fabricated using the same mask.

It should be noted that the hierarchical structure of the film layers of the array substrate 100 in the embodiments of the present disclosure is not limited to the architecture shown in FIG. 4 but could also be the architecture shown in FIG. 5. Please refer to FIG. 5, which shows a schematic diagram of the hierarchical structure of the film layers of the array substrate 100 according to one or more embodiments of the present disclosure. In FIG. 5, the first metal layer 13 is disposed on the substrate 11, and the first insulating layer 14 covers the first metal layer 13. The first metal layer 13 includes the gate 130, the scanning line (scan), and a common routing line 131. The active layer 15 is disposed on the first insulating layer 14. The second metal layer 16 is disposed on the active layer 15, and includes the source 162, the drain 164, and the data line (data). The source 162 and the drain 164 are connected to the active layer 15. The pixel electrode layer 18 is disposed on the first insulating layer 14, and includes the second electrode p2, which is connected to the drain 164. The second insulating layer 17 covers the pixel electrode layer 18. The common electrode layer 12 is disposed on the second insulating layer 17, and includes the first electrode p1, which is connected to the common routing line 131. In the thickness direction of the array substrate 100, the second electrode p2 and the first electrode p1 are arranged to overlap each other.

Optionally, in some embodiments, both the common electrode layer 12 and the pixel electrode layer 18 are made of transparent conductive materials, which can be metal oxides such as indium tin oxide or indium zinc oxide, etc.

In some embodiments, the first electrode p1 is a planar electrode. In the top view of the array substrate 100, the second electrode p2 overlaps with the first electrode p1.

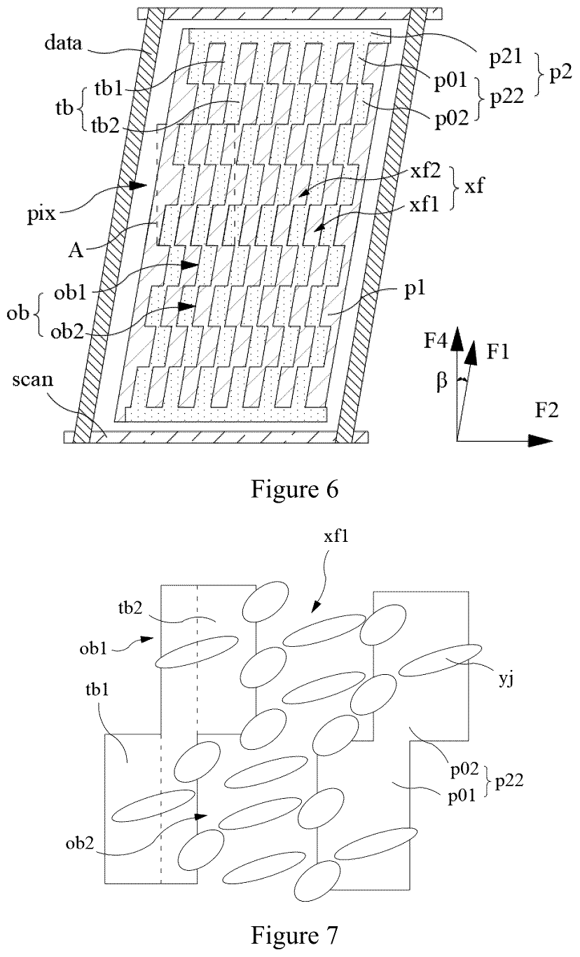

As shown in FIG. 6, the second electrode p2 includes an edge electrode p21 and a plurality of branch electrodes p22. The plurality of branch electrodes p22 are connected to one side of the edge electrode p21 and extend along the first direction F1. The first direction F1 intersects with the extension direction of the scanning line (scan). The plurality of branch electrodes p22 are arranged at intervals along the second direction F2, which is parallel to the extension direction of the scanning line (scan), with a slit xf formed between two adjacent branch electrodes p22.

In the top view of the array substrate 100, the side of the branch electrode p22 close to the slit xf is featured with concave portions ob and convex portions tb. In the first direction F1, the concave portions ob and the convex portions tb are alternately arranged.

It should be understood that an electric field is generated between the second electrode p2 and the first electrode p1 to drive liquid crystal to deflect. The edge region of the second electrode p2 exhibits the strongest electric field intensity, where the response speed of the liquid crystal is the fastest. By intermolecular forces, the liquid crystal in this area will bring the liquid crystal in adjacent areas to rotate together. As shown in FIG. 7, the array substrate 100 of the embodiments of the present disclosure employs a branch electrode p22 with alternately arranged concave portions ob and convex portions tb in the first direction F1, to increase the area of the edge region of the second electrode p2, allowing more liquid crystal yj to be distributed in the edge region of the second electrode p2, thereby bringing more surrounding liquid crystal yj to rotate simultaneously, accelerating the overall response speed of the liquid crystal yj.

Optionally, the edge electrode p21 extends along the second direction F2, but is not limited to this. The edge electrode p21 is connected to the opposite end of the branch electrode p22.

Optionally, an angle β between the first direction F1 and a fourth direction F4, which is perpendicular to the second direction F2, is in a range of 5 degrees to 20 degrees. In other words, the angle β between the extension direction of the branch electrode p22 and the fourth direction F4 is in the range of 5 degrees to 20 degrees.

It can be understood that the greater the angle β, the greater the viewing angle, and the lower the brightness at the direct viewing angle. Therefore, when considering both brightness and viewing angle, the angle β is selected to be in the range of 5 degrees to 20 degrees. For example, it can be 5 degrees, 6 degrees, 7 degrees, 8 degrees, 9 degrees, 10 degrees, 11 degrees, 12 degrees, 13 degrees, 14 degrees, 15 degrees, 16 degrees, 17 degrees, 18 degrees, 19 degrees, or 20 degrees.

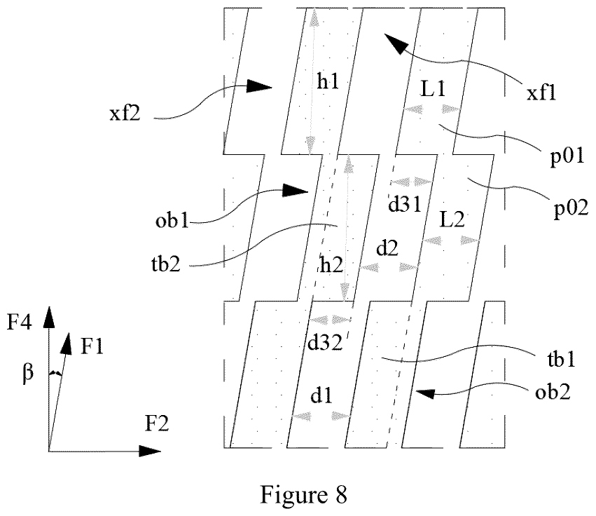

Please refer to FIG. 6 and FIG. 8. Optionally, in some embodiments of the present disclosure, the branch electrode p22 includes a first segment p01 and a second segment p02. A plurality of slits xf include a first slit xf1 and a second slit xf2 alternately arranged along the second direction F2. The convex portion tb includes a first convex portion tb1 and a second convex portion tb2, and the concave portion ob includes a first concave portion ob1 and a second concave portion ob2.

In the top view of the array substrate 100, in the first direction F1, the first segment p01 and the second segment p02 are arranged in alternative connections, and the first segment p01 and the second segment p02 are partially overlapped. The first segment p01 protrudes from the second segment p02 in the direction towards the first slit xf1, forming the first convex portion tb1. Meanwhile, the second segment p02 recesses into the first segment p01 in the direction towards the first slit xf1, forming the first concave portion ob1.

In the array substrate 100 of the embodiments of the present disclosure, the first convex portion tb1 and the first concave portion ob1 are arranged near the first slit xf1 to increase the area of the second electrode p2 that corresponds to the edge region of the first slit xf1, so that more liquid crystal yj can be distributed in the edge region. As a result, more surrounding liquid crystal yj can be brought to rotate simultaneously, thereby accelerating the overall response speed of the liquid crystal yj.

Optionally, in some embodiments of the present disclosure, in the top view of the array substrate 100, the first segment p01 recesses into the second segment p02 in the direction towards the second slit xf2, forming the second concave portion ob2, while the second segment p02 protrudes from the first segment in the direction towards the first slit xf1, forming the second convex portion tb2.

In the array substrate 100 of the embodiments of the present disclosure, the second convex portion tb2 and the second concave portion ob2 are arranged near the second slit xf2 to increase the area of the second electrode p2 that corresponds to the edge region of the second slit xf2, so that more liquid crystal yj can be distributed in the edge region of the second slit xf2. As a result, more surrounding liquid crystal yj can be brought to rotate simultaneously, thereby accelerating the overall response speed of the liquid crystal yj.

Optionally, in some embodiments of the present disclosure, in the top view of the array substrate 100, a plurality of the first segments p01 are arranged in alignment along the second direction F2, and a plurality of the second segments p02 are arranged in alignment along the second direction F2.

In other words, a row of the first segments p01 and a row of the second segments p02 are alternately arranged along the first direction F1 to enhance the uniformity of the arrangement, so that the visual brightness and viewing angles from the left and right perspectives are tended to be equal.

Optionally, in some embodiments of the present disclosure, in the second direction F2, a distance d1 between two adjacent first segments p01 is equal to a distance d2 between two adjacent second segments p02. However, this is not limited to such an arrangement; for instance, the distance d1 between two adjacent first segments p01 can also be different from the distance d2 between two adjacent second segments p02.

It can be understood that the distance d1 between the first segments p01 is a width of the slit xf corresponding to the first segments p01, and the distance d2 between the second segments p02 is a width of the slit xf corresponding to the second segments p02. The distances d1 and d2 being equal enhances the symmetry of the left and right viewing angles, reducing the risk of discrepancies between the two.

Optionally, in some embodiments of the present disclosure, in the second direction F2, the distance d1 between two adjacent first segments p01 and the distance d2 between two adjacent second segments p02 are in a range of 1.5 micrometers to 6 micrometers respectively. A width L31 of the first concave portion ob1 and a width L32 of the second concave portion ob2 are in a range of 0.5 micrometer to 2 micrometers respectively.

It can be understood that as the width L31 of the first concave portion ob1 and the width L32 of the second concave portion ob2 increase, the distance d1 between two adjacent first segments p01 and the distance d2 between two adjacent second segments p02 also increase. As the distance d1 and the distance d2 increase, the driving force of electric field exerted on the liquid crystal in the middle of the slit xf becomes weaker, resulting in a slower overall response speed of the liquid crystal. Conversely, if the distance d1 is too small, there is a risk of unexpected connection.

Therefore, based on the requirements for both of them, the selected distance d1 and distance d2 should be in the range of 1.5 micrometers to 6 micrometers respectively. The width L31 of the first concave portion ob1 and the width L32 of the second concave portion ob2 should be in the range of 0.5 micrometer to 2 micrometers respectively. This ensures that the two adjacent branch electrodes p22 do not connect to each other and improves the overall response speed of the liquid crystal.

Optionally, the distance d1 between two adjacent first segments (p01) and the distance d2 between two adjacent second segments (p02) should be in the range of 1.5 micrometers to 6 micrometers respectively. For instance, they can be 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, 3.0 micrometers, 3.1 micrometers, 3.2 micrometers, 3.3 micrometers, 3.4 micrometers, 3.5 micrometers, 3.6 micrometers, 3.7 micrometers, 3.8 micrometers, 3.9 micrometers, 4.0 micrometers, 4.1 micrometers, 4.2 micrometers, 4.3 micrometers, 4.4 micrometers, 4.5 micrometers, 4.6 micrometers, 4.7 micrometers, 4.8 micrometers, 4.9 micrometers, 5.0 micrometers, 5.1 micrometers, 5.2 micrometers, 5.3 micrometers, 5.4 micrometers, 5.5 micrometers, 5.6 micrometers, 5.7 micrometers, 5.8 micrometers, 5.9 micrometers, or 6.0 micrometers.

The width L31 of the first concave portion ob1 and the width L32 of the second concave portion ob2 are in a range of 0.5 micrometer to 2 micrometers respectively. For example, they can be 0.5 micrometer, 0.6 micrometer, 0.7 micrometer, 0.8 micrometer, 0.9 micrometer, 1.0 micrometer, 1.1 micrometers, 1.2 micrometers, 1.3 micrometers, 1.4 micrometers, 1.5 micrometers, 1.6 micrometers, 1.7 micrometers, 1.8 micrometers, 1.9 micrometers, or 2.0 micrometers.

Optionally, in some embodiments of the present disclosure, in the second direction F2, a width L1 of the first segment p01 and a width L2 of the second segment p02 are in a range of 1.5 micrometers to 4 micrometers respectively. In the fourth direction F4, which is perpendicular to the second direction F2, a length h1 of the first segment p01 and a length h2 of the second segment p02 are in a range of 2 micrometers to 8 micrometers respectively. Furthermore, the difference between the length h1 of the first segment p01 and the length h2 of the second segment p02 is less than or equal to 3 micrometers.

It can be understood that the greater the width L1 of the first segment p01 and the width L2 of the second segment p02, the weaker the driving force of electric field exerted on the liquid crystal in the middle of the first segment p01 and the second segment p02, resulting in a slower overall response speed of the liquid crystal. Conversely, the smaller the width L1 and the width L2, the more unstable the fabrication process will be.

Based on the requirements of the fabrication process and the response speed of the liquid crystal, the widths L1 and the width L2 are selected to be in the range of 1.5 micrometers to 4 micrometers to ensure the stability of the two adjacent branch electrodes p22 and to improve the overall response speed of the liquid crystal. Optionally, the width L1 and the width L2 can be 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, 3.0 micrometers, 3.1 micrometers, 3.2 micrometers, 3.3 micrometers, 3.4 micrometers, 3.5 micrometers, 3.6 micrometers, 3.7 micrometers, 3.8 micrometers, 3.9 micrometers, or 4.0 micrometers.

Secondly, the gearter the lengths h1 of the first segment p01 and h2 of the second segment p02, the easier the preparation during the fabrication process, and the greater the areas of the first segment p01 and the second segment p02 in the first direction F1. However, the smaller the number of rows that can be set for the first segment p01 and the second segment p02, the lower the uniformity of the arrangement will be. Therefore, based on considerations of the fabrication process and arrangement uniformity, the length h1 of the first segment p01 and the length h2 of the second segment p02 are selected to be in the range of 2 micrometers to 8 micrometers, and the difference between the length h1 of the first segment p01 and the length h2 of the second segment p02 is less than or equal to 3 micrometers.

For example, the length h1 of the first segment p01 and the length h2 of the second segment p02 can be 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, 3.0 micrometers, 3.1 micrometers, 3.2 micrometers, 3.3 micrometers, 3.4 micrometers, 3.5 micrometers, 3.6 micrometers, 3.7 micrometers, 3.8 micrometers, 3.9 micrometers, 4.0 micrometers, 4.1 micrometers, 4.2 micrometers, 4.3 micrometers, 4.4 micrometers, 4.5 micrometers, 4.6 micrometers, 4.7 micrometers, 4.8 micrometers, 4.9 micrometers, 5.0 micrometers, 5.1 micrometers, 5.2 micrometers, 5.3 micrometers, 5.4 micrometers, 5.5 micrometers, 5.6 micrometers, 5.7 micrometers, 5.8 micrometers, 5.9 micrometers, 6.0 micrometers, 7.1 micrometers, 7.2 micrometers, 7.3 micrometers, 7.4 micrometers, 7.5 micrometers, 7.6 micrometers, 7.7 micrometers, 7.8 micrometers, 7.9 micrometers, or 8.0 micrometers.

The difference between the length h1 of the first segment p01 and the length h2 of the second segment p02 can be 0 micrometer, 0.1 micrometer, 0.2 micrometer, 0.3 micrometer, 0.4 micrometer, 0.5 micrometer, 0.6 micrometer, 0.7 micrometer, 0.8 micrometer, 0.9 micrometer, 1.0 micrometer, 1.1 micrometers, 1.2 micrometers, 1.3 micrometers, 1.4 micrometers, 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, or 3.0 micrometers.

Optionally, the length h1 of the first segment p01 can be greater than, less than, or equal to the length h2 of the second segment p02.

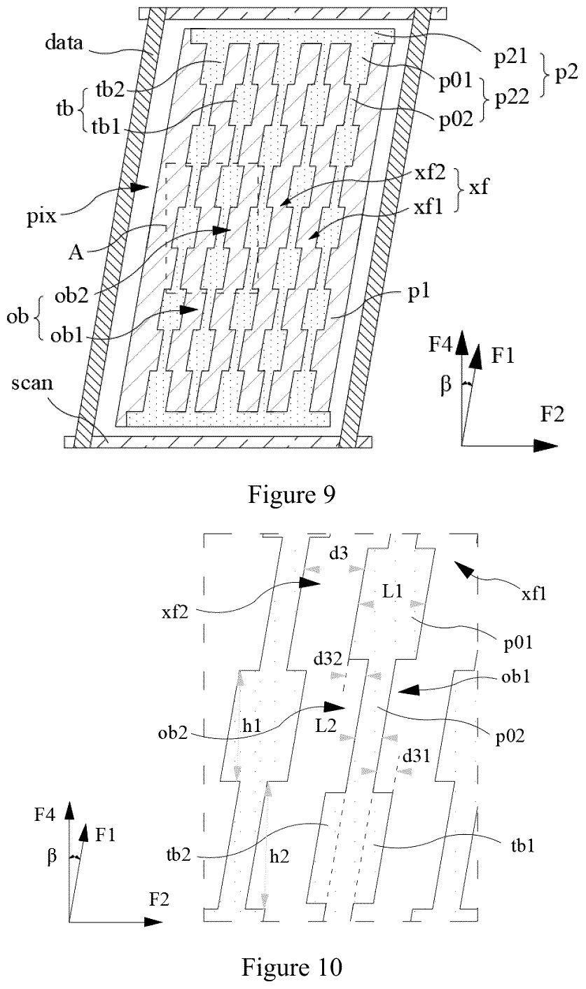

Please refer to FIG. 9 and FIG. 10. FIG. 9 shows a schematic diagram of a pixel region according to one or more embodiments of this present disclosure. FIG. 10 is an enlarged schematic diagram of part A shown in FIG. 9.

In FIG. 9 and FIG. 10, parts that differ from the previous embodiments will be described to avoid redundancy. In the top view of the array substrate 100, the first segment p01 protrudes from the second segment p02 in the direction towards the second slit xf2, forming a second convex portion tb2, and the second segment p02 recesses into the first segment p01 towards the second slit xf2, forming the second concave portion ob2.

In the array substrate 100 in the embodiments of the present disclosure, the second convex portion tb2 and the second concave portion ob2 are arranged near the second slit xf2 to increase the area of the second electrode p2 that corresponds to the edge region of the second slit xf2, so that more liquid crystal yj can be distributed in the edge region of the second electrode p2. As a result, more surrounding liquid crystal yj can be brought to rotate simultaneously, thereby accelerating the overall response speed of the liquid crystal yj.

In some embodiments of the present disclosure, in the top view of the array substrate 100, the first segment p01 and the second segment p02 are alternately arranged along the second direction F2.

Compared to the embodiment shown in FIG. 6, the first segment p01 and the second segment p02 in the embodiment shown in FIG. 9 are arranged alternately along both the first direction F1 and the second direction F2, so that the uniformity of the arrangement of the first segment p01 and the second segment p02 is further improved, thereby enhancing the uniformity of visible brightness.

Optionally, in some embodiments of the present disclosure, in the second direction F2, a distance d3 between adjacent first segment p01 and second segment p02 is in a range of 1.5 micrometers to 6 micrometers. Additionally, the width L31 of the first concave portion ob1 and the width L32 of the second concave portion ob2 are in a range of 0.25 micrometer to 1 micrometer respectively.

It can be understood that the distance d3 between adjacent first segment p01 and the second segment p02 corresponds to a width of the slit xf between the first segment p01 and the second segment p02. As the width L31 of the first concave portion ob1 and the width L32 of the second concave portion ob2 increase, the distance d3 between adjacent first segment p01 and the second segment p02 also increases. As the distance d3 increases, the driving force of electric field exerted on the liquid crystal in the middle of the slit xf becomes weaker, resulting in a slower overall response speed of the liquid crystal. Conversely, if the distance d3 is too small, there is a risk of unexpected connection.

Therefore, based on the requirements for both of them, the distance d3 is selected in the range of 1.5 micrometers to 6 micrometers, and the width L31 and the width L32 are selected in the range of 0.25 micrometer and 1 micrometer respectively. This ensures that two adjacent branch electrodes p22 do not connect to each other and improves the overall response speed of the liquid crystal.

Optionally, the distance d3 between adjacent first segment p01 and second segment p02 can be 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, 3.0 micrometers, 3.1 micrometers, 3.2 micrometers, 3.3 micrometers, 3.4 micrometers, 3.5 micrometers, 3.6 micrometers, 3.7 micrometers, 3.8 micrometers, 3.9 micrometers, 4.0 micrometers, 4.1 micrometers, 4.2 micrometers, 4.3 micrometers, 4.4 micrometers, 4.5 micrometers, 4.6 micrometers, 4.7 micrometers, 4.8 micrometers, 4.9 micrometers, 5.0 micrometers, 5.1 micrometers, 5.2 micrometers, 5.3 micrometers, 5.4 micrometers, 5.5 micrometers, 5.6 micrometers, 5.7 micrometers 5.8 micrometers, 5.9 micrometers, or 6.0 micrometers.

The width L31 of the first concave portion ob1 and the width L32 of the second concave portion ob2 can be 0.25 micrometer, 0.26 micrometer, 0.27 micrometer, 0.28 micrometer, 0.29 micrometer, 0.3 micrometer, 0.31 micrometer, 0.32 micrometer, 0.33 micrometer, 0.34 micrometer, 0.35 micrometer, 0.36 micrometer, 0.37 micrometer, 0.38 micrometer, 0.39 micrometer, 0.4 micrometer, 0.42 micrometer, 0.45 micrometer, 0.48 micrometer, 0.52 micrometer, 0.55 micrometer, 0.58 micrometer, 0.62 micrometer, 0.65 micrometer, 0.68 micrometer, 0.72 micrometer, 0.75 micrometer, 0.78 micrometer, 0.82 micrometer, 0.85 micrometer, 0.88 micrometer, 0.92 micrometer, 0.95 micrometer, 0.98 micrometer, or 1 micrometer.

Optionally, in some embodiments of the present disclosure, in the second direction F2, the width L1 of the first segment p01 is greater than the width L2 of the second segment p02, with the difference between the width L1 of the first segment p01 and the width L2 of the second segment p02 being in a range of 0.5 micrometer to 2 micrometers. In a direction perpendicular to the second direction F2, the length h1 of the first segment p01 is less than the length h2 of the second segment p02, with the difference between the length h1 of the first segment p01 and the length h2 of the second segment p02 being less than or equal to 3 micrometers.

It can be understood that the width L1 of the first segment p01 is greater than the width of the second segment p02, so that the second segment p02 can be correspondingly disposed in the middle of two adjacent first segments p01. Consequently, this arrangement forms the first concave portion ob1 and the second concave portion ob2 on both sides of the second segment p02, while the first segment p01 protrudes from both sides of the second segment p02, forming the first convex portion tb1 and the second convex portion tb2.

A difference between the width L1 of the first segment p01 and the width L2 of the second segment p02 is in a range of 0.5 micrometer to 2 micrometers to ensure that the width L1 and the width L2 are not significantly different, thereby minimizing the variation in liquid crystal deflection. Optionally, the difference between the widths L1 and L2 can be 0.5 micrometer, 0.6 micrometer, 0.7 micrometer, 0.8 micrometer, 0.9 micrometer, 1.0 micrometer, 1.1 micrometers, 1.2 micrometers, 1.3 micrometers, 1.4 micrometers, 1.5 micrometers, 1.6 micrometers, 1.7 micrometers, 1.8 micrometers, 1.9 micrometers, or 2.0 micrometers.

Additionally, in a direction perpendicular to the second direction F2, a length h1 of the first segment p01 is less than a length h2 of the second segment p02, so that the distance between one row of the first segment p01 and an adjacent row of the first segment p01 increases, reducing the risk of the connection between two adjacent rows of the first segment p01. In this case, it ensures that the width of the same slit xf along the first direction F1 is more uniform, thus reducing the risk of liquid crystal misalignment.

The difference between the length h1 of the first segment p01 and the length h2 of the second segment p02 is less than or equal to 3 micrometers. The difference between the length h1 of the first segment p01 and the length h2 of the second segment p02 can be 0.1 micrometer, 0.2 micrometer, 0.3 micrometer, 0.4 micrometer, 0.5 micrometer, 0.6 micrometer, 0.7 micrometer, 0.8 micrometer, 0.9 micrometer, 1.0 micrometer, 1.1 micrometers, 1.2 micrometers, 1.3 micrometers, 1.4 micrometers, 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, or 3.0 micrometers.

Additionally, the width L1 of the first segment p01, the width L2 of the second segment p02, the length h1 of the first segment p01, and the length h2 of the second segment p02 can refer to the selected values in the aforementioned embodiments, which will not be reiterated here.

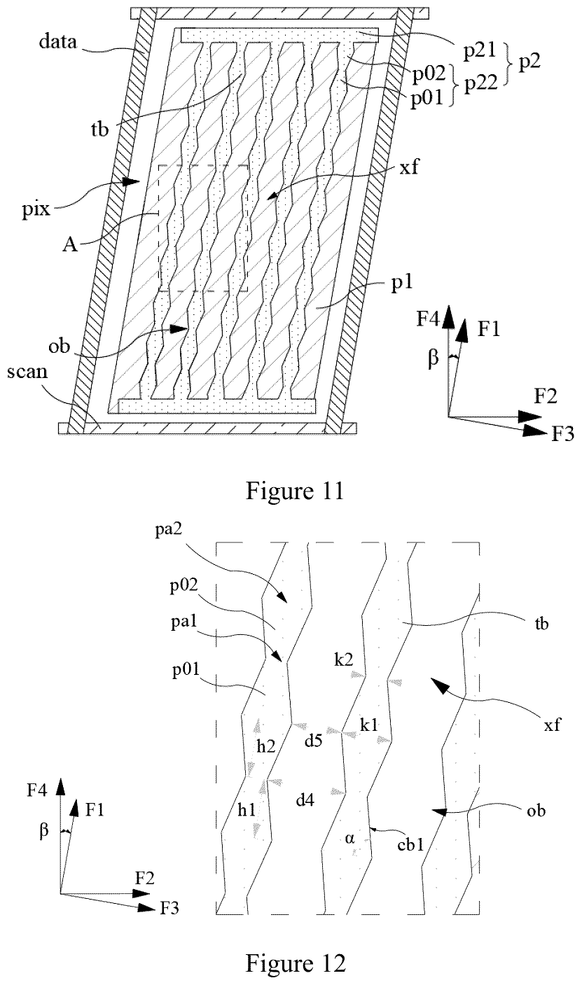

Please refer to FIG. 11 and FIG. 12. FIG. 11 shows a schematic diagram of a pixel region according to one or more embodiments of this present disclosure. FIG. 12 shows an enlarged schematic diagram of part A shown in FIG. 11.

In FIG. 11 and FIG. 12, to avoid redundancy, only parts that differ from the aforementioned embodiments are described. In some embodiments of the present disclosure, the branch electrode p22 includes a first segment p01 and a second segment p02.

In the top view of the array substrate 100, in the first direction F1, the width L1 of the first segment p01 gradually decreases, and the width L2 of the second segment p02 gradually increases. The first segment p01 and the second segment p02 are arranged in alternate connections, and the narrow end of the first segment p01 is connected to the narrow end of the second segment p02 to form a concave portion ob, while the wide end of the first segment p01 is connected to the wide end of the second segment p02 to form a convex portion tb.

Compared to the aforementioned embodiment, the connection between the convex portion tb and the concave portion ob in the embodiments corresponding to FIG. 11 is more gentle, so that the central axis of the slit xf extends along the first direction F1, reducing the risk of bending of the slit xf, and thus reducing the risk of liquid crystal misalignment and improving light transmittance.

Optionally, in some embodiments of the present disclosure, in the top view of the array substrate 100, a plurality of the first segments p01 are arranged in alignment along a third direction F3, which is perpendicular to the first direction F1, and a plurality of the second segments p02 are arranged in alignment along the third direction F3.

The first segment p01 and the second segment p02 are respectively arranged along the third direction F3, which can widen the viewing angle.

Optionally, in some embodiments of the present disclosure, the narrow end of the first segment p01 and the narrow end of the second segment p02 are connected to form a first connecting surface pa1 extending along the third direction F3, and the wide end of the first segment p01 and the wide end of the second segment p02 are connected to form a second connecting surface pa2 extending along the third direction F3.

In the top view of the array substrate 100, the pattern of the first segment p01 and the pattern of the second segment p02 are symmetrically arranged with respect to the first connecting surface pa1, and the pattern of the first segment p01 and the pattern of the second segment p02 are symmetrically arranged with respect to the second connecting surface pa2.

It should be noted that the narrow end refers to a relatively narrow end surface, and the wide end refers to a relatively wide end surface. The first connecting surface pa1 is the common plane of the narrow end between the first segment p01 and the narrow end of the second segment p02, while the second connecting surface pa2 is the common plane between the wide end of the first segment p01 and the wide end of the second segment p02. Therefore, the shape and size of the first connecting surface pa1 are equal to those of the narrow end, and the shape and size of the second connecting surface pa2 are equal to those of the wide end.

It is understood that the symmetrical arrangement of the patterns of the first segment p01 and the second segment p02 achieves a more gentle connection between the convex portion tb and the concave portion ob, and in this case, achieves a more gentle edge of the slit xf, thereby reducing the risk of liquid crystal misalignment and improving light transmittance.

Optionally, in some embodiments of the present disclosure, in the top view of the array substrate 100, in the third direction F3, a ratio of the width k1 of the wide end to a width k2 of the narrow end of the first segment p01 is in a range of 1.2 to 1.8. In the first direction F1, a length h1 of the first segment p01 is in a range of 1 micrometer to 5 micrometers.

It can be understood that the greater the ratio of the width k1 of the wide end to the width k2 of the narrow end of the first segment p01, the higher the degree of narrowing of the side of the first segment p01, the greater the degree of edge bending of the branch electrode p22, and the higher the risk of liquid crystal misalignment. However, the greater the edge region of the branch electrode p22, the faster the overall response speed of the liquid crystal. The longer the length h1 of the first segment p01, the edge folding line of the branch electrode p22 can have a more gentle transition, making the connection between the concave portion ob and the convex portion tb become more gentle, which can reduce the risk of liquid crystal misalignment. Therefore, based on the premise of improving the overall response speed of the liquid crystal and in order to mitigate the risk of liquid crystal misalignment, the ratio of the width k1 of the wide end of the first segment p01 to the width k2 of the narrow end of the first segment p01 can be selected to be in a range of 1.2 to 1.8, and the length h1 of the first segment p01 can be in a range of 1 micrometer to 5 micrometers.

For instance, the ratio of the width k1 of the wide end to the width k2 of the narrow end of the first segment p01 can be 1.2, 1.3, 1.4, 1.5, 1.6, 1.7, or 1.8.

The length h1 of the first segment p01 can be 1 micrometer, 1.1 micrometers, 1.2 micrometers, 1.3 micrometers, 1.4 micrometers, 1.5 micrometers, 1.6 micrometers, 1.7 micrometers, 1.8 micrometers, 1.9 micrometers, 2.0 micrometers, 2.1 micrometers, 2.2 micrometers, 2.3 micrometers, 2.4 micrometers, 2.5 micrometers, 2.6 micrometers, 2.7 micrometers, 2.8 micrometers, 2.9 micrometers, 3.0 micrometers, 3.1 micrometers, 3.2 micrometers, 3.3 micrometers, 3.4 micrometers, 3.5 micrometers, 3.6 micrometers, 3.7 micrometers, 3.8 micrometers, 3.9 micrometers, 4.0 micrometers, 4.1 micrometers, 4.2 micrometers, 4.3 micrometers, 4.4 micrometers, 4.5 micrometers, 4.6 micrometers, 4.7 micrometers, 4.8 micrometers, 4.9 micrometers, or 5.0 micrometers.

The length h2 of the second segment p02 is equal to the length h1 of the first segment p01, but it is not limited to this; for instance, the length h2 of the second segment p02 can be different from the length h1 of the first segment p01. The width k2 of the narrow end of the first segment p01 is equal to the width of the narrow end of the second segment p02, and the width k1 of the wide end of the first segment p01 is equal to the width of the wide end of the second segment p02.

Optionally, the selected values of the width k1 of the wide end and the width k2 of the narrow end of the first segment p01 can refer to the selected values of the width L1 of the first segment in the aforementioned embodiments, which are not reiterated here.

Optionally, in some embodiments of the present disclosure, in the third direction F3, the sum of a distance d4 between the narrow ends of two adjacent first segments p01 with the width k2 of one narrow end of one first segment p01 is equal to the sum of a distance d5 between the wide ends of two adjacent first segments p01 with the width k1 of one wide end of the first segment p01.

Such a configuration improves the periodicity of the arrangement of the branch electrodes p22 and the slits xf, thereby enhancing the uniformity of the arrangement.

Optionally, in some embodiments of the present disclosure, in the top view of the array substrate 100, the first segment p01 includes a side cb1. The side cb1 is connected to the narrow end and the wide end of the first segment p01, and the angle α between the side cb1 and the wide end of the first segment p01 is in a range of 45 degrees and 85 degrees.

It can be understood that the greater the angle α, the connection between the convex portion tb and the concave portion ob becomes more gentle, but the smaller the edge region of the branch electrode p22, which affects the overall response speed of the liquid crystal. Therefore, based on the premise of improving the overall response speed of the liquid crystal, the connection between the convex portion tb and the concave portion ob is more gentle, thereby increasing the light transmittance.

Optionally, the angle α can be 45 degrees, 50 degrees, 55 degrees, 60 degrees, 65 degrees, 70 degrees, 75 degrees, 80 degrees, or 85 degrees.

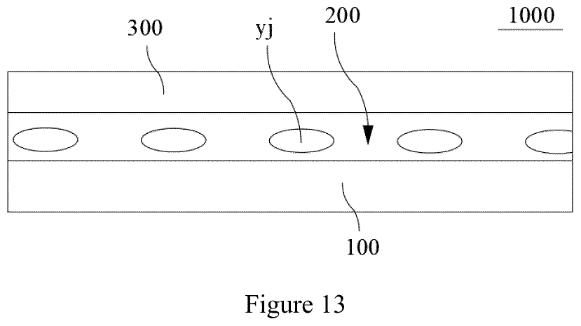

As shown in FIG. 13, which shows a schematic diagram of the structure of the display panel 1000 according to one or more embodiments of the present disclosure. The display panel 1000 includes an opposed substrate 300, a liquid crystal layer 200, and the array substrate 100 as described in any of the above embodiments, with the liquid crystal layer 200 disposed between the opposed substrate 300 and the array substrate 100.

It should be noted that the array substrate 100 of the display panel 1000 in the embodiments of the present disclosure is similar or identical in structure to the array substrate 100 described in any of the aforementioned embodiments. For specific details, please refer to FIGS. 3 to 12, which will not be repeated here.

It should be noted that in the display panel 1000 of the embodiments of the present disclosure, an electric field is generated between the second electrode p2 and the first electrode p1 to drive liquid crystal to deflect. The edge region of the second electrode p2 exhibits the strongest electric field intensity, where the response speed of the liquid crystal is the fastest., By intermolecular forces, the liquid crystal in this area will bring the liquid crystal in adjacent areas to rotate together. In the embodiments of the present disclosure, the array substrate 100 of the display panel 1000 employs a branch electrode p22 with alternately arranged concave portions ob and convex portions tb in the first direction F1, to increase the area of the edge region of the second electrode p2, allowing more liquid crystal yj to be distributed in the edge region of the second electrode p2, thereby bringing more surrounding liquid crystal yj rotate simultaneously, accelerating the overall response speed of the liquid crystal yj.

Optionally, in some embodiments of the present disclosure, the angle between the first direction F1 and the fourth direction F4, which is perpendicular to the second direction F2, is in a range of 5 degrees to 20 degrees. The liquid crystal yj in the liquid crystal layer 200 is a positive liquid crystal, and the alignment direction of the liquid crystal yj forms an angle of less than 45 degrees with the extension direction of the slit xf; or the liquid crystal yj in the liquid crystal layer 200 is a negative liquid crystal, and the alignment direction of the liquid crystal yj forms an angle of greater than 45 degrees with the extension direction of the slit xf.

It should be understood that the alignment direction of the liquid crystal yj is the long-axis direction when the liquid crystal yj is not deflected. Specifically, the greater the angle of the liquid crystal yj, the lower the light transmittance and the faster the response speed. Therefore, the aforementioned configurations meet the requirements for light transmittance and response speed.

Optionally, the alignment direction of the positive liquid crystal yj and the extension direction of the slit xf can form an angle of 5 degrees, 10 degrees, 15 degrees, 20 degrees, 25 degrees, 30 degrees, 35 degrees, or 40 degrees. The alignment direction of the negative liquid crystal yj and the extension direction of the slit xf can form an angle of 50 degrees, 55 degrees, 60 degrees, 65 degrees, 70 degrees, 75 degrees, 80 degrees, or 85 degrees.

In some embodiments of the present disclosure, the liquid crystal layer 200 contains a nematic liquid crystal and also includes a chiral agent. The chiral agent constitutes 0.01% to 0.5% of the total mass of the liquid crystal layer 200, and the pitch of the liquid crystal yj is in a range of 30 micrometers to 1000 micrometers.

The addition of the chiral agent to the nematic liquid crystal can enhance light transmittance. However, if the pitch of the liquid crystal yj is too small, it will reduce the response speed of the liquid crystal. Conversely, if the pitch is too large, it will increase the risk of misalignment. Therefore, the pitch of the liquid crystal yj can be further selected to be in a range of 60 micrometers to 300 micrometers to better mitigate the risk of misalignment while meeting the response speed of the liquid crystal.

Optionally, the chiral agent accounts for 0.01%, 0.02%, 0.03%, 0.04%, 0.05%, 0.06%, 0.07%, 0.08%, 0.09%, 0.1%, 0.15%, 0.2%, 0.25%, 0.3%, 0.35%, 0.4%, 0.45%, or 0.5% of the total mass of the liquid crystal layer 200.

The pitch of the liquid crystal yj can be 60 micrometers, 70 micrometers, 80 micrometers, 90 micrometers, 100 micrometers, 110 micrometers, 120 micrometers, 130 micrometers, 140 micrometers, 150 micrometers, 160 micrometers, 170 micrometers, 180 micrometers, 190 micrometers, 200 micrometers, 210 micrometers, 220 micrometers, 230 micrometers, 240 micrometers, 250 micrometers, 260 micrometers, 270 micrometers, 280 micrometers, 290 micrometers, or 300 micrometers.

The array substrate in the embodiments of the present disclosure includes a first electrode and a second electrode. The second electrode includes an edge electrode and a plurality of branch electrodes. The plurality of branch electrodes are connected to one side of the edge electrode and extend along the first direction. The plurality of branch electrodes are arranged at intervals along the second direction, forming slits between two adjacent branch electrodes. In the top view of the array substrate, the side of the branch electrode close to the slit is featured with the concave portions and the convex portions that are alternately arranged in the first direction.

It should be understood that an electric field is generated between the second electrode and the first electrode. The edge region of the second electrode exhibits the strongest field intensity, where response speed of the liquid crystal is the fastest. By intermolecular forces, the liquid crystal in this area will bring the liquid crystals in adjacent areas to rotate together. The array substrate in the embodiments employs a branched electrode with alternating concave portions and convex portions in the first direction, to increase the area of the edge region of the second electrode, allowing more liquid crystals to be distributed in the edge region of the second electrode, thereby bringing more surrounding liquid crystals to rotate simultaneously, accelerating the overall response speed of the liquid crystals.

The above provides a detailed description of an array substrate and a display panel according to one or more embodiments of the present disclosure. Specific examples have been provided to elaborate on the principles and implementations of the present disclosure. The description of the above embodiments is intended only to assist in understanding the methods and core concepts of the present disclosure. Moreover, those skilled in the art may make modifications to the specific implementation methods and present disclosure scope based on the ideas presented in this present disclosure. In summary, the content of this specification should not be construed as limiting the present disclosure.

What is claimed is:

1. An array substrate, comprising:
a scanning line;
a data line, intersecting with the scanning line to form a plurality of pixel regions; and
a first electrode and a second electrode, disposed in the pixel regions, wherein the first electrode and the second electrode are disposed on different layers, and the first electrode and the second electrode are configured to drive liquid crystal to deflect, one of the first electrode and the second electrode is a pixel electrode while the other of the first electrode and the second electrode is a common electrode, the first electrode is a planar electrode, and in a top view of the array substrate, the second electrode overlaps with the first electrode;
wherein the second electrode comprises an edge electrode and a plurality of branch electrodes, the plurality of branch electrodes are connected to one side of the edge electrode and extend along a first direction intersecting with an extension direction of the scanning line, the plurality of branch electrodes are arranged at intervals along a second direction, which is parallel to the extension direction of the scanning line, and a slit is formed between two adjacent branch electrodes; and
wherein in the top view of the array substrate, the side of the branch electrode close to the slit is featured with concave portions and convex portions, and in the first direction, the concave portions and the convex portions are alternately arranged.

2. The array substrate according to claim 1, wherein the branch electrode comprises a first segment and a second segment, the plurality of slits comprise a first slit and a second slit alternately arranged along the second direction, the convex portion comprises a first convex portion, and the concave portion comprises a first concave portion;
in the top view of the array substrate, in the first direction, the first segment and the second segment are arranged in alternative connections, the first segment and the second segment are partially overlapped, and the first segment protrudes from the second segment in the direction towards the first slit, forming the first convex portion, while the second segment recesses into the first segment in the direction towards the first slit, forming the first concave portion.

3. The array substrate according to claim 2, wherein the convex portion comprises a second convex portion, and the concave portion comprises a second concave portion, in the top view of the array substrate, the first segment recesses into the second segment in the direction towards the second slit, forming the second concave portion, and the second segment protrudes from the first segment in the direction towards the first slit, forming the second convex portion.

4. The array substrate according to claim 3, wherein in the top view of the array substrate, a plurality of the first segments are arranged in alignment along the second direction, and a plurality of the second segments are arranged in alignment along the second direction.

5. The array substrate according to claim 4, wherein in the second direction, a distance between two adjacent first segments and a distance between two adjacent second segments are in a range of 1.5 micrometers to 6 micrometers respectively, and a width of the first concave portion and a width of the second concave portion are in a range of 0.5 micrometer to 2 micrometers respectively.

6. The array substrate according to claim 5, wherein in the second direction, a width of the first segment and a width of the second segment are in a range of 1.5 micrometers to 4 micrometers respectively, in a direction perpendicular to the second direction, a length of the first segment and a length of the second segment are in a range of 2 micrometers to 8 micrometers respectively, and a difference between the length of the first segment and the length of the second segment is less than or equal to 3 micrometers.

7. The array substrate according to claim 2, wherein the convex portion comprises a second convex portion and the concave portion comprises a second concave portion, in the top view of the array substrate, the first segment protrudes from the second segment in the direction towards the second slit, forming the second convex portion, while the second segment recesses into the first segment towards the second slit, forming the second concave portion.

8. The array substrate according to claim 7, wherein in the top view of the array substrate, the first segment and the second segment are alternately arranged along the second direction.

9. The array substrate according to claim 8, wherein in the second direction, a distance between adjacent first segment and second segment is in a range of 1.5 micrometers to 6 micrometers, and a width of the first concave portion and a width of the second concave portion are in a range of 0.25 micrometer to 1 micrometer respectively.

10. The array substrate according to claim 9, wherein in the second direction, a width of the first segment is greater than a width of the second segment, with a difference between the width of the first segment and the width of the second segment being in a range of 0.5 micrometer to 2 micrometers, and wherein in a direction perpendicular to the second direction, a length of the first segment is less than a length of the second segment, with the difference between the length of the first segment and the length of the second segment being less than or equal to 3 micrometers.

11. The array substrate according to claim 1, wherein the branch electrode comprises a first segment and a second segment;
in the top view of the array substrate, in the first direction, a width of the first segment gradually decreases, a width of the second segment gradually increases, the first segment and the second segment are arranged in alternative connections, and the narrow end of the first segment is connected to the narrow end of the second segment to form a concave portion, while the wide end of the first segment is connected to the wide end of the second segment to form a convex portion.

12. The array substrate according to claim 11, wherein in the top view of the array substrate, a plurality of the first segments are arranged in alignment along a third direction perpendicular to the first direction, and a plurality of the second segments are arranged in alignment along the third direction perpendicular to the first direction.

13. The array substrate according to claim 12, wherein the narrow end of the first segment and the narrow end of the second segment are connected to form a first connecting surface extending along the third direction, and the wide end of the first segment and the wide end of the second segment are connected to form a second connecting surface extending along the third direction;
in a top view plan of the array substrate, a pattern of the first segment and a pattern of the second segment are symmetrically arranged with respect to the first connecting surface, and the pattern of the first segment and the pattern of the second segment are symmetrically arranged with respect to the second connecting surface.

14. The array substrate according to claim 12, wherein in the top view of the array substrate, in the third direction, a ratio of a width of the wide end to a width of the narrow end of the first segment is in a range of 1.2 to 1.8; and
in the first direction, a length of the first segment is in a range of 1 micrometer to 5 micrometers.

15. The array substrate according to claim 14, wherein in the third direction, a sum of a distance between the narrow ends of two adjacent first segments with the width of one narrow end of the first segment is equal to the sum of a distance between the wide ends of two adjacent first segments with the width of one wide end of the first segment.

16. A display panel, comprising an opposed substrate, a liquid crystal layer, and an array substrate, wherein the liquid crystal layer is disposed between the opposed substrate and the array substrate; the array substrate comprises:
a scanning line;
a data line, intersecting with the scanning line to form a plurality of pixel regions; and
a first electrode and a second electrode, disposed in the pixel regions, wherein the first electrode and the second electrode are disposed on different layers, and the first electrode and the second electrode are configured to drive liquid crystal to deflect, one of the first electrode and the second electrode is a pixel electrode while the other of the first electrode and the second electrode is a common electrode, the first electrode is a planar electrode, and in a top view of the array substrate, the second electrode overlaps with the first electrode;
wherein the second electrode comprises an edge electrode and a plurality of branch electrodes, the plurality of branch electrodes are connected to one side of the edge electrode and extend along a first direction intersecting with an extension direction of the scanning line, the plurality of branch electrodes are arranged at intervals along a second direction, which is parallel to the extension direction of the scanning line, and a slit is formed between two adjacent branch electrodes; and
wherein in a top view of the array substrate, the side of the branch electrode close to the slit is featured with concave portions and convex portions, and in the first direction, the concave portions and the convex portions are alternately arranged.

17. The display panel according to claim 16, wherein an angle between the first direction and a fourth direction perpendicular to the second direction, is in a range of 5 degrees to 20 degrees; and
the liquid crystal in the liquid crystal layer is a positive liquid crystal, and an angle between the alignment direction of the liquid crystal and the extension direction of the slit is less than 45 degrees; or the liquid crystal in the liquid crystal layer is a negative liquid crystal, and an angle between the alignment direction of the liquid crystal and the extension direction of the slit is greater than 45 degrees.

18. The display panel according to claim 16, wherein the liquid crystal of the liquid crystal layer is a nematic liquid crystal, and the liquid crystal layer further comprises a chiral agent, wherein the chiral agent accounts for 0.01% to 0.5% of the total mass of the liquid crystal layer, and the pitch of the liquid crystal is in a range of 30 micrometers to 1000 micrometers.
